(19) United States
(12) Patent Application Publication
(10) Pub. No.: US 2022/0027531 A1
(43) Pub. Date: Jan. 27, 2022

(54) Method and system for structural information on-demand

(71) Applicants: Eilan Choi, Oakton, VA (US); John Sun, Herndon, VA (US)

(72) Inventors: EILAN CHOI, OAKTON, VA (US); JOHN SUN, HERNDON, VA (US)

(73) Assignee: STREAM METHODS, INC., HERNDON, VA (US)

(21) Appl. No.: 17/384,776

(22) Filed: Jul. 25, 2021

Related U.S. Application Data
(60) Provisional application No. 63/056,641, filed on Jul. 26, 2020.

(51) Int. Cl. G06F 30/13; G06T 7/00; G06T 15/08

(52) U.S. Cl. CPC G06F 30/13; G06F 2119/02; G06T 15/08; G06T 7/0004

(57) ABSTRACT

A data system and processes that generate structural characteristics and analytics such as various elevations and heights of a structure. Information produced in on-demand fashion and can be certified. It combines human intelligence with machine intelligence to achieve optimal results. Information produced by the system are significant for many purposes, including Flood Risk Assessment, Flood Insurance Rating, and Flood Impacting Threshold (FIT) determination. The system further generates various derivatives such as Flood Impacting Threshold Score (FITS), precise Flood Risk Ratings (e.g. PrecisionRating,) building conditions and valuation. The system generates such information on-demand by computer vision, artificial intelligence, sensors, image analysis, statistical analysis, and mathematical analysis through a Graphic User Interface (GUI) or machine-to-machine, and Application Programming Interface (API.)

This application claims priority to U.S. Provisional Patent Application No. 63/056,641 filed on July 26, 2020, the entire content of which is incorporated herein by reference.

### BACKGROUND OF THE INVENTION

The present invention encompasses a data system of multiple components and subparts that manages and generates structural characteristics and analytics information. Structure or site elevations and heights among the produced are significant for many purposes, including flood risk assessment, flood insurance rating, and determining Flood Impacting Threshold (FIT). Based on such information, the present invention further generates various derivatives such as Flood Impacting Threshold Score (FITS), precise flood risk ratings (e.g. PrecisionRating,), building conditions, and valuation. The present invention generates such information on-demand by computer vision, artificial intelligence, sensors, image analysis, statistical analysis, and mathematical analysis involving graphic user interfaces (GUI) or machine-to-machine Application Programming Interfaces (API.) The present invention includes revolutionary processes for certification and improvement based on “extra” inputs such as an uploaded photo of better quality, which combines human intelligence with “machine intelligence” to greatly increase products' reliability and accuracy.

Acquiring, retrieving, determining, estimating, calculating, and serving structures' characteristics and analytics are complex processes, often requiring professionals and surveyors on-site to conduct measurement and calculation, post-process the raw data collected from the field to produce the final output, implement storing and retrieving mechanisms, and serve the data through certain media or system interfaces. These processes are time-consuming, labor-intensive, and costly. Scale of availability and accessibility are common and constant issues. To this point, it often takes days or weeks in advance to make an appointment and let the field crew acquire structure elevations and other characteristics of a structure on-site, assuming no previous records exist for easy retrieval. The present invention alleviates, even eliminates, such pains and headaches. As an example, for decades elevation certification, a key process in rating flood risk insurance, relies on measurements on-site by professionals; acquiring an elevation certificate costs hundreds even thousands of dollars, which is a major bottleneck that hinders the overall risk rating process and a satisfactory customer experience. To this point and to our best knowledge, there has not been any pragmatic methods and systems for generating and serving structure characteristics on a large scale (e.g. regional, national, or global scale,) for any buildings, on-demand, and low-cost. The present invention and its novel approaches reduce the duration by 50 times or more, and as a result tremendously expedite business processes such as rating flood insurance premiums. The associated cost is only a fraction of those by conventional ways. The present invention serves on-demand structure characteristics through various protocols including web services, which frees consuming parties from setting up and maintaining such a system.

At present, no existing system or method that offers comparable systems, solutions, and resulting products in a comparable fashion as the present invention does. Because of its tremendous practicality, the present invention is a game-changer.

### BRIEF DESCRIPTION OF THE INVENTION

The present invention encompasses a data system of multiple components and a process of subparts that acquires, retrieves, determines, estimates, produces, and serves structure characteristics and analytics. Structures/sites/features' elevations and heights are among the produced, which are of great value for various purposes including flood risk assessment, flood insurance rating, Flood Impacting Threshold (FIT) determination, flood risk communication. Based on such information, the present invention further generates various derivatives such as Flood Impacting Threshold Score (FITS) and precise flood risk ratings (e.g. PrecisionRating,), building conditions, building valuation, etc. The present invention performs through various means including computer vision, artificial intelligence, sensors on devices, image analysis, statistical analysis, mathematical analysis, etc. The present invention utilizes various devices and serves structure characteristics and analytics on-demand, through a graphic user interface (GUI) or machine-to-machine, system-to-system application programming interface (API.) The present invention serves its products on-demand. It also includes revolutionary processes for certification and improvement based on “extra” inputs such as an uploaded photo of better quality, which combines human intelligence with “machine intelligence” to greatly increase products' reliability and accuracy.

One feature of the present invention stores various building characteristics and analytics in databases utilizing various mechanisms including by unique IDs, by structure footprint IDs and locations, by location coordinates, by geographic features, and by geometric features. Such databases, for example, include one in which building characteristics information are linked to and organized by building footprints with a unique ID.

Another feature of the present invention retrieves, manages, and serves such information on-demand through various protocols. The present invention organizes and manages massive amounts of inputs and base layers, which are necessary for acquiring, retrieving, determining, and serving structure characteristics and analytics. Building footprint layer, for example, plays a critical role in many processes; many pieces of building information can be organized based on this layer. Such information is acquired by the system with or without human involvement using artificial intelligence (AI), computer vision (CV) module, machine-to-machine application programming interface (API,) mobile devices-to-server request module, or a client-server system. The machine-to-machine API empowers a client system to make requests over the network remotely or locally. For example, the “Elevation API” is implemented for machine-to-machine interactions to acquire and serve elevation information over the network. Other APIs include “Building Info API” and “Building Footprint API.”

Another feature of the present invention runs and rerun various models based on new inputs, such as an uploaded photo of better quality, marked up images, a photo with a prepositioned object of known shapes and dimension, a height estimates by user, a user specified point location, a user digitized feature polygon, etc.

Another feature of the present invention certifies its products by a user or a professional. It combines human intelligence and judgement with machine intelligence to generate best products.

Another feature of the present invention displays various information in various forms on a screen of device. Graphic User Interface (GUI) and associated back-end processes allow users to see the information, also to interact with the processes by performing actions such as accepting or rejecting, accepting, certifying, adjusting, requesting re-runs, inputting, etc. The present invention displays “elevation information” to include a picture/photo of a structure with “real world” elevations and heights (e.g. water surface elevations and structure elevations/heights) marked on the picture.

Another feature of the present invention determines the location of a feature or an object by GPS readings, or through a map interface and converting image/map coordinates to real-world coordinates. It describes locations using various coordinate systems including one relative to the picture/image, one relative to a screen, and real-world coordinates. The present invention determines “measure points” associated with a feature on an image/picture. (e.g. the location of the door in the picture of a house.) The present invention performs address matching, which determines the location of a mailing address or a location descriptor. It also performs “reverse geocoding” that determines the mailing address from coordinates such as latitude and longitude.

Another feature of the present invention automatically detects and extracts objects/features (e.g. a door, building's rooftop, driveway, etc.) from a photo/image/imagery. It measures objects and features based on a reference object of known dimensions. It determines vertical references of a structure or site such as top-of-slab at garage. It generates information such as Lowest Adjacent Grade (LAG), Highest Adjacent Grade (HAG), Median Adjacent Grade (MAG), elevations (e.g. at the door, of top of slab, first floor, basement floor, etc.), and heights (e.g. floor height about slab, door bottom to underlying terrain, etc.)

Another feature of the present invention is to predict structure characteristics by statistical methods (e.g. first floor elevation based on adjacent grades and location of a building.)

Another feature of the present invention estimates various elevations and heights based on underlying terrain model, such as, a Digital Elevation Model (DEM.)

Yet another feature of the present invention is to produce various derivatives and analytics for various purposes based on the Structure information and Analytics produced. For example, once structure elevation is determined and water surface elevation of flooding events are known or modeled, precise depth information at the structure level is calculated, based on which precise risk indicators and insurance premium can be calculated. The present invention determines flood water depth, Flood Impacting Threshold (FIT), Water Entrance Threshold (WET,) precise risk premium ratings such as PrecisionRating, Annualized Average Depth (AAD), and determination of above-or-below (AoB) water surface.

### BRIEF DESCRIPTION OF THE DRAWINGS

FIG. 1 illustrates key components of the system for acquiring, retrieving, determining, estimating, calculating, producing, and serving structure information, characteristics, and analytics.

FIG. 1-1 illustrates individual components are assembled to generate products

FIG. 2 illustrates the ElevationAPI for Structure and Site Elevations.

FIG. 3 illustrates the Certification Process of an Elevation Certification.

FIG. 4 illustrates the Graphic User Interface (GUI) Display of an On-Demand Structural Information System.

FIG. 5 illustrates an example of On-Demand Elevation and Height GUI Display.

FIG. 6 illustrates the process of Elevation Calculation of an Object Using Sensors (camera).

FIG. 7 illustrates an example of Calculating Dimensions of a Target Object/Feature based on a reference object of Known Dimensions.

FIG. 8 illustrates the relationship between Flood Impact Threshold (FIT) and Water Surface Elevation & Structure Elevation.

FIG. 9 illustrates results of various Flood Impact Threshold (FIT) Products.

FIG. 10 illustrates an example of a Comparison of Flood Impact Threshold (FIT) Scores Among Buildings.

FIG. 11 illustrates an example of PrecisionRating, setting lower and upper boundaries.

### DETAILED DESCRIPTION OF THE INVENTION

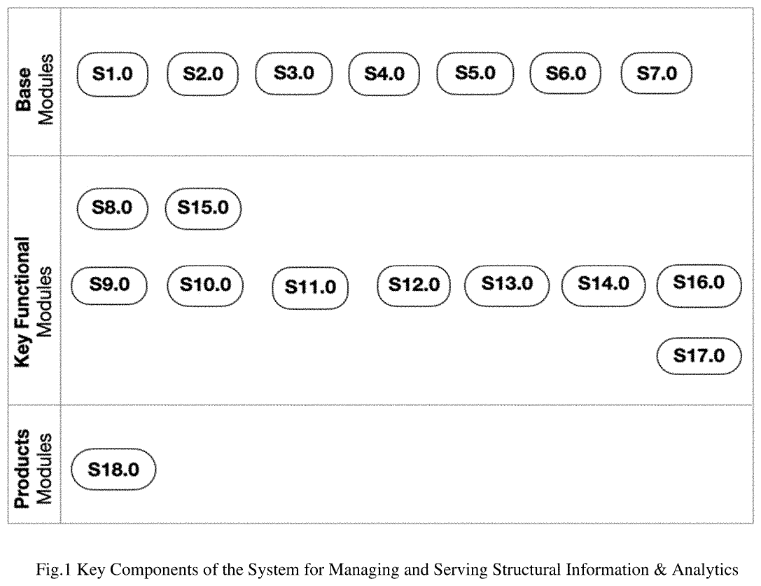

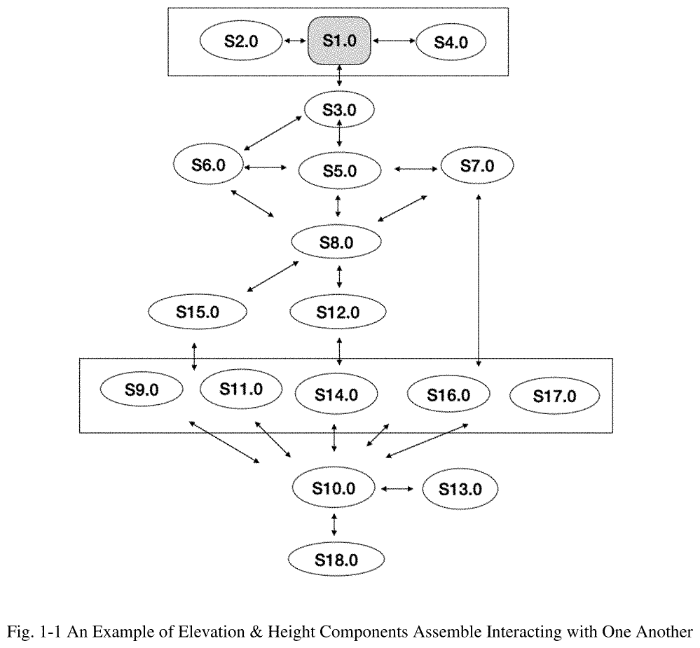

Referring to FIG. 1, Key components of the system for acquiring, retrieving, determining, estimating, calculating, producing, and serving structure information, characteristics, and analytics, the present invention comprises multiple modules and methods which function either independently or jointly. All components in FIG. 1 are listed below:

S1.0: Data Storage Module

S2.0: Data Retrieval and Query Module

S3.0: Data Serving Module

S4.0: Input Data Management Module

S5.0: Interaction & Communication Module

S6.0: GUI & Display Module

S7.0: Data Acquisition, User Inputs, and Processing Module

S8.0: Location Processing & Determination Module

S9.0: Statistical and Regression Module

S10.0: Elevations and Heights Module

S11.0: Image/Imagery Analysis Module

S12.0: Observing & Sensing Module

S13.0: Certification Module

S14.0 Artificial Intelligence (AI) and Computer Vision (CV) Module

S15.0: Observation, Analytical, and Management Module

S16.0: Z-Reference Module

S17.0: VirtualSurvey(P2H2E) Module

S18.0: Derivative, Visualization, and Product Module

Some foundational building blocks, commonly shared among the components above, include the following:

i. Hardware and software powering them (e.g. storage device, mobile device, CPU, RAM, ROM, sensors, camera, display screen, mouse, tappable screen, etc.)

j. Operating Systems (e.g. Windows and Linux OS)

k. Server software (e.g. a web server)

l. Databases (e.g. MySQL, SQL Server, etc.)

m. Front-end technologies (e.g. browsers, APIs, HTML, CSS, JavaScript frameworks, etc.)

n. Back-end technologies (e.g. C#, Python, .Net framework, etc.)

o. Geographic Information System technologies (e.g. ESRI ArcGIS, Google Map, etc.)

p. Machine Learning platforms and technologies (e.g. TensorFlow, Convoluted Neural Network, etc.)

The components function either individually or jointly. The present invention assembles them in various ways to achieve different purposes. FIG. 1-1 illustrates one use case, “components interact with each other to produce elevations, heights, and derivatives.” To produce structure elevations and heights, Data Storage Module (S1.0) is utilized for storing everything including massive base layers of inputs such as terrain and building footprints. The Query & Retrieval Module (S2.0) enables dynamic interactions between the storage and other components. It also interacts with Input Data Module (S4.0) to accept inputs directly from other sources including direct user inputs. From here, the system SERVES information through Data Serving Module (S3.0) by delivering them either on a display though GUI & Display Module (S6.0), or a machine-to-machine API through Interaction & Communicating Module (S5.0). Once a target of interest is accurately located by Location Processing & Determination Module (S8.0), the observation-Analytical-Management Module (S15.0) and Observing & Sensing (S12.0) acquire observation and other information about the target. Such information can be a satellite imagery, a side-view photo of a structure, GPS reading, camera settings, or other sensor-generated data and metadata.

Based on such information, the System determines elevations and height by multiple modules including Statistical & Regression Module (S9.0), Imagery Analysis Module (S11.0), Artificial Intelligence & Computer Vision Module (S14.0). The system often sets a vertical reference of a structure through the Z-reference Module (S16.0). The VirtualSurvey Module (S17.0) measures dimensions of object and features based on a reference object of known dimensions. Elevations and Heights Module (S10.0) produces various optimized and finalized data products through Certification Module (S17.0), where a human being can accept, certify, reject, rerun, adjust, etc. Based on elevations and heights produced, the Derivative Module (S18.0) further produces information such as Flood Impacting Threshold Scores (FITS), PrecisionRating, water depth information, etc. Each Module in FIG. 1 and FIG. 1-1 are further described in below.

### S1.0 Data Storage Module

The Data Storage Module provides all storage-related functionalities necessary for the present invention to perform. The functionalities include storing information dynamically or statically by using unique identifiers, such as building identifiers, and geographic feature identifiers. The module stores structure information as attributes associated with building footprints, geographic coordinates, street address, geographic features, and geometrical objects (point, line, polygon, rectangles, bounding boxes, etc.) The module consists of databases where relevant information and metadata is also stored, including site/structure elevations (e.g. Lowest Adjacent Grade, Highest Adjacent Grade, etc.) various structure elevations (e.g. Top-of-slab), various height objects (e.g. Floor Height, door heights), object and feature locations, building type, building style, building foundation type, building condition, basement information, garage information, valuation of building, stair counts, etc. It also stores certification and change information. The scale of the databases is global, the sizes massive and rapidly growing.

### S2.0 Data Retrieval and Query Module

The Data Retrieval and Query Module performs information retrieval and query functionalities. It queries and retrieves information by using unique identifiers, such as building identifiers and bridge identifiers. It also queries and retrieves structure information by structure footprints, coordinates, geographic coordinates, geometry objects, geography, etc. It performs spatial operation and selection by using various information including location, coordinates, geography, geographic features (points, lines, polygons,) street address, etc. In combination with other modules, this module performs on-demand data query and retrieval initiated by a remote request through the network.

### S3.0 Data Serving Module

Data Serving Module serves building information, characteristics, and analytics over network and on-demand. It handles requests initiated remotely by a user, an application, or a machine, and responds accordingly by producing, preparing, delivering the requested information by following various industry-standard protocols and Application Programming Interfaces (APIs.) This module is critical for creating practical values, without which, the value of the present invention would be greatly limited.

### S4.0 Input Data Management Module

This module comprises data, functionalities, and algorithms that handle input needs of the system. It comprises all data and meta-data, including Digital Elevation Models, building footprints, roads, floodplains maps and databases, imageries, photos, pictures, and other base layers. Continuously or periodically, this module performs updates on the base layers. Pre-assembling key input layers empowers such on-demand production services.

### S5.0 Interaction and Communication Module

Interaction and Communication Module handles the interaction and communication among various system components, between the system and its users, and between a remote device and the server machine. This module includes machine-to-machine APIs, or Application Programming Interface, which specify various forms of requests and responses, e.g. parameters, values, actions, outputs, metadata, etc.

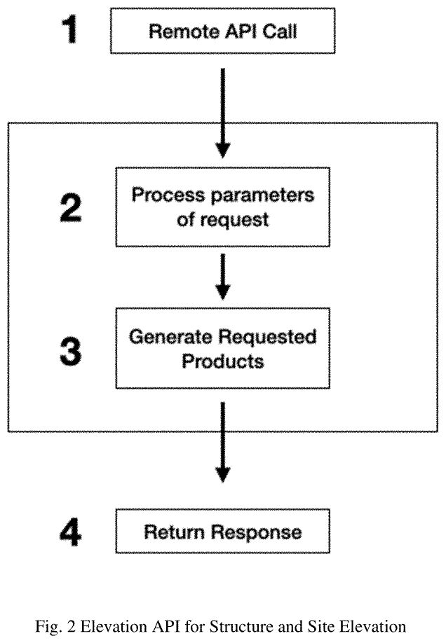

An Elevation API as depicted in FIG. 2, is the first of its kind for remotely serving structure and site elevation information on-demand. In Step 1, following industry-standard protocols, a Remote API Call collects and passes various parameter-value pairs to request one or more products. The ElevationAPl defines the structure of request messages and wraps parameter-value pairs for transmission over the network. A request message contains all necessary information to request a service to deliver one or more products. Examples of such information include credentials, product names to be requested, product specifications, location descriptor, street address, location's coordinates, latitude, longitude, machine address, web service name, protocols to be used, user inputs such as heights, and geometry objects (lines, polygons, points, bounding boxes, on-screen digitized objects,) user acceptation or rejection of a certain value, data or address of pictures to send to server, markup of pictures, user inputs of numerical values or textual values (e.g. basement or not, story height, etc.), and others.

Upon receiving the request message through user interface or a remote API call, as in Step 2 of FIG. 2, the system parses out the contents wrapped and geolocates the building of interest (by unique ID, coordinates, address, description, or user input by clicking on a map). In Step 3, the System constructs geometry objects (e.g. building footprint,) identifies which tile of Digital Elevation Model to use, and then elevates the geometry objects, calculates elevations (e.g. Lowest Adjacent Grade, Highest Adjacent Grade, Median Adjacent Grade, garage floor elevations, Top-of-slab elevation, elevation at door, lowest floor elevation, first floor elevation, etc.), and calculates various heights (e.g. First Floor Height, Floor Height over a reference level.) In Step 4, the ElevationAPl defines data structures and forms of various responses sent back to the requester. The message wraps the products requested (e.g. LAG, HAG, MAG, structure heights, elevations, etc.) along with all relevant information and metadata (e.g. DEM resolution, vertical datum, coordinate system, horizontal unit, and vertical unit, etc.)

The system fulfills the request by delivering the requested data products over the network by following industry standard protocols. Products delivered through ElevationAPl include:

Product IDs, Lowest Adjacent Grade, Highest Adjacent Grade, Median Adjacent Grade, Metadata (e.g. Digital terrain resolution, vertical datum, Z-unit, etc.), Structure Elevation (floor elevations, garage floor elevation, top-of-slab elevation, etc.), floor heights, and other relevant information.

### S6.0 Graphic User Interface (GUI) and Display Module

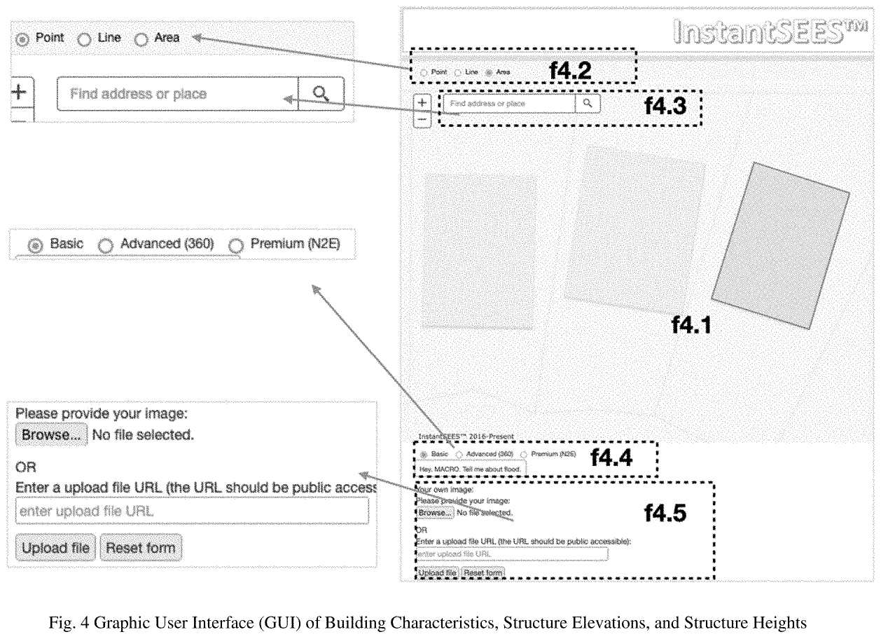

This module provides all functionalities related to displaying information for the purposes of presenting information and interacting with a human user. It comprises both front-end and back-end processes to enable various functions and features. Specifically, it provides a GUI to facilitate determining and estimating structure characteristics, such as structure/site elevations and heights. This GUI, as illustrated partly in FIG. 4, comprises various elements and functionalities such as a map-image control display (FIG. 4, f4.1) where geo-referenced layers, imageries, and photos are displayed and manipulated, and with which a user can interact (by tapping, clicking, dragging, etc.) to specify location and vertices of features and objects (e.g. a building, a door, a region of a photo, etc.) Its features includes displaying images or maps, on-screen digitizing/drawing (FIG. 4, f4.2) of objects or features (e.g. points, lines, polygons, bounding boxes, etc.), panning, zooming, inputting attributes, labeling graphic elements/objects/features, address matching/geocoding (FIG. 4, f4.3) that can turn a street address or location description into coordinates, one or more controls for collecting users inputs (not illustrated in FIG. 4) by clicking, dragging, tapping, typing, or other actions. The GUI runs on various applications such as various web browsers, and on various devices such as standalone computers, mobile phones, and tablets. The GUI can interact with sensors on device such as camera and through Augmented Reality and Virtual Reality (ARVR) supported by the device and system, and it manipulates graphical elements through “live view” and perform measurement on the device screen.

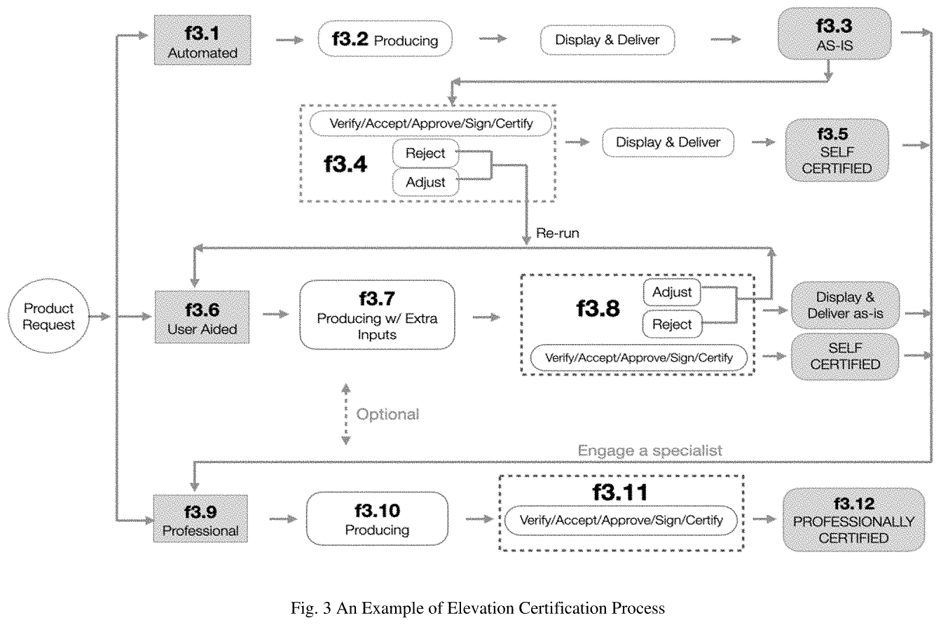

The system displays information such as elevations of a building/site, and provide various features and tools for the users to take certain actions regarding the results (e.g. display, verify, adjust objects, approve, reject, appeal, self-certify, professionally certify, sign, rerun, request assistance, providing inputs, uploading pictures, mark up, print, download the information, etc.,) by interacting with graphic controls on screen, such as clicking on a button in a browser, selecting an item from the menu of the browser or tapping on a button in an app on a mobile device. (Some of the means are also illustrated in FIG. 3 as part of the Certification Module.) As an example, the present invention offers Elevation Certificate on demand. Interactive controls allow users verify results, approve, or reject the results (by selecting an element control such as a checkbox, a radio button, or other types of controls.) Interactive controls allow users to request further assistance from the system or another human. Interactive controls allow users provide extra inputs or modify/adjust input parameters or objects (e.g. adjusting the bounding box of an object) and request re-runs. Interactive controls allow users to approve, reject, or self-certify results such as the Elevation Certificate provided by the present invention. Interactive controls allow users to request a “professionally certified” product certificate. Various graphic controls allow users to print the Elevation Certificate or download the file to the device in use.

The present invention's GUI includes functions and tools for requesting products and services based on multiple means and workflows. For example, a user can obtain data products (e.g. structure elevations and heights) through a fully automated process with minimum user inputs, re-running models to achieve better results based on extra inputs from users, or engaging a professional specialist. (These workflows are partly illustrated in FIG. 4, f4.4.)

The present invention provides tools and features (FIG. 4, f4.5) for specifying a picture source/location to be used for producing structure information. This picture can be a local file, or at a remote location. The GUI accepts the path provided by a user, acquire that data, and use it to generate desired results. Similarly, the present invention provides interface for activating camera on a mobile device, taking a picture, attributing, or marking up the picture, and uploading it to the System to produce requested results. It submits the photo along with other relevant data and metadata (e.g. camera settings, GPS readings, barometric readings, etc.) to a remote machine for further processing. It also allows the picture taker to pre-position a reference object of human/machine recognizable shape and patterns of known dimension before the picture is taken. It offers a feature to optionally mark up the picture before sending it for processing (e.g. drawing bounding boxes of objects and features). The system generates auto-detection of objects and features based on the picture submitted, and provides features and tools for the user to interact with and manipulate the machine-generated results (e.g. adjust the autodetected objects, correct locations, etc.)

### S7.0 Data Acquisition and User Inputs Processing Module

The present invention acquires and processes various data and user inputs to produce desired results. This module comprises various mechanisms, both front-end and back-end, for the system to gather user inputs and instructions. These inputs include numerical or non-numerical parameters such as dimensions, heights, object type, building type, building categories, consisting of basement or not, single story or multi-story, etc. For example, through its interfaces, the module allows users to directly input their estimate or measurement of an object/feature, such as door height, dimensions, and floor height above terrain. These inputs also include photos, imageries, drawings, etc. The present invention has features to allow adjusted actions and instructions user can perform or instruct the system to perform.

FIG. 3 illustrates some of the means regarding certification and handling of user inputs and judgements to aid the various processes to generate best results (e.g. elevations or heights.) The module allows a user to interact with the system by adding his or her judgement and inputs such as verification, acceptance, rejection, approval, appeal, modification, or adjustment (FIGS. 3—f3.4, f3.8, f3.11) by directly interacting with the system through its interfaces and back-end processes. It further allows a user to self-certify or request a professional to certify (FIGS. 3—f3.5, f3.12) the information requested. The module also allows users to provide inputs and instructions to the system by manipulating graphics on screen; resizing, adjusting, or dragging a polygon (e.g. rectangle, bounding box) to a new position would result a new set of coordinates and dimensions of the polygon, which would be provided to the system to generate more accurate results.

This module offers users to draw and mark up on screen such as digitizing a building footprint to be used for calculating Lowest Adjacent Grade and Highest Adjacent Grade, and draw a geometry feature (point, line, polygon) on screen and attribute it. Markups on image tells the system certain meanings of the marked elements, such as an object (e.g. a door), bottom edge of the door, terrain line, roof of a building, driveway, etc. For example, user can mark a bounding box around a door, a line indicating the terrain under the door, and one or more pixels indicating where the terrain is. Positions of all markups on picture are described by a coordinate system of the image based on which, distance can be measured on image. For example, measuring the vertical difference of top and bottom of a door tells the system the door height in pixels. The measurement of pixel count can be converted into real-world units (e.g. inch, foot, meter, etc.)

This module has a novel method for users to include a pre-positioned reference object of human/machine-recognizable shape/pattern and known dimensions before a picture taken and sent for processing. For example, a piece of legal-sized printing paper can be taped on the front door before a picture is taken so that AI-CV module can easily detect and extract the object and elements in the picture can be accurately measured based on the piece of paper of known dimensions (e.g. 8×10″ .) This module provides users with options to specify a data resource' location, remotely or on-site, so that they can be acquired and used by the present invention to produce and deliver desired results. For example, a user or system can specify network address of local or remote picture, or a service network service providing picture. Using this address, the present invention accesses the source specified by the address to acquire the picture, process it, and produce data such as building elevation, terrain elevation, or other building characteristics.

This module allows users to specify locations of interest (e.g. a measure point of a building's location, door location, driveway location, garage door location, etc.) by clicking on an image to indicate the accurate location for the system to process and measure. These are valuable inputs for aiding automated processes to avoid poor and false predictions. For example, to determine the floor elevation behind a door, the present invention automatically predicts the exact door location first. In case such a location is wrong, then the resulted floor elevation would be wrong. Providing users with an ortho imagery or a side-view photo of the building, a user can simply click on the location of the door and the location is fed to the system. Such a measure point has higher reliability and accuracy, resulting in better predictions and better products. Again, this is another example how the present invention combines human intelligence and “machine intelligence.”

This module provides users with functions of taking and uploading photos of structures to be used for estimating building characteristics. The present invention also acquires various images and photos from sources such as Google StreetView to be processed by artificial intelligence and computer vision module to detect and extract object and features such as doors. But often, there is no such observation data available from the source (e.g. Google StreetView). Even if it is available and successfully acquired, often the quality of image does not support the purpose of detecting and predicting. For example, it is common that a sideview photo acquired from Google StreetView was taken too far away, exposure was too high or too low, and the door of the building looks too small, dark, and fuzzy, etc. When artificial intelligence and computer vision module process such a photo for object (e.g. door) detection and measurement, the resulted accuracy would be low. Therefore, to overcome the big challenge of “no observation, obsolete observation, or poor observation,” the present invention integrates “user provided observation” which is of better quality, currency, resolution, discernibility, etc. Again, this simple but powerful feature solved a big problem in the real world. It is of great practical value partly because the ubiquity of high-resolution cameras on a mobile phone. This module acquires readings and metadata from sensors from a remote device. For example, from a remote device, the system acquires GPS readings, camera settings, accelerometer readings, time series, temperature, barometer readings, etc.

The greatest challenge of providing digital products and services on a large scale lies in the reliability and accuracy of the offering, which are dominant factors for the practical value. The present invention's fully integrated and seamless Certification process (for self- or professional certification), along with utilizing user judgement and extra inputs (e.g. better locations, higher-resolution photos of structure for extracting and measuring objects and features, estimates of floor height, etc.) greatly improve the accuracy and reliability of offered products while still allowing timely or even instant delivery and low-cost. System features such as bringing in extra user inputs, uploading a better photo of structure, self-certifying, etc. may seem to be mundane, but once “assembled” into the overall processes of present invention, they function as a whole and generate reliable and accurate results. At its core, the present invention combines human and machine intelligence to offer users best results, timely delivery, and low-cost.

### S8.0 Location Processing and Determination Module

Locating is a fundamental function of the present invention. Locating is the process of acquiring coordinates for a geographic feature, a physical object, or a virtual object. The Location Processing and Determination Module comprises locating functions based on user or system inputs such as a location descriptor (e.g. mailing address or interactions) and a converted location from a map (geo-referenced) interface. This module also comprises functions that utilizing GPS sensors. This module converts coordinates of the screen into real-world coordinates. The Module automatically determines locations of feature of interest in a picture/imagery, which is critical for processes such as elevation determination.

For example, in order to determine a feature's elevation above terrain, the present invention needs to pinpoint the location of the feature first so that the terrain elevation can be determined from Digital Elevation Model. This module determines the location of the “MeasurePoint” through various methods. For example, it directly does so based on users' input, such as click on a geo-referenced map or ortho-view imagery. This module also determines and assigns real-world coordinates to an element of a photo. It can determine the location by first determining the feature's relative location to another feature, such as “southeast corner of the building,” then further deriving coordinates of the feature of interest based on the known coordinates of the building footprint.

### S9.0 Statistical and Regression Module

Often observation data is limited for a specific structure. As a result, it is often difficult or impossible to determine the structure characteristics purely based on observation data. For example, when there is no side-view picture of the structure, one cannot directly tell where a door is or the elevation at the door. In such situations, the present invention performs various statistical operations based on “group observation data” rather than observation data collected at the individual structure or site level. For example, there may be no side-view image for a specific house, but there are plenty of data collected in its vicinity, based on which regression equations between various structure characteristics and miscellaneous factors (e.g. neighborhood characteristics, terrain characteristics, etc.) are established. Using these correlations, regressions, and other identified trends and patterns, the present invention predicts characteristics of a specific building of a certain “group.” To do this, massive group-level datasets need to be collected, often millions of data points.

The present invention builds regression equations between a certain structure elevation/height (e.g. floor elevations, or floor height at a door) and adjacent grades of the structure. Lowest, Highest, and Median Adjacent Grades (LAG/HAG/MAG) can be calculated based on a building footprint polygon and the underlying terrain elevation model. By using such regression equations established, floor elevation/height can be predicted. To cover the entire globe, one regression equation does not fit all. The present invention divides the globe into different regions and groups of various sizes and shapes. (For example, multiple regressions are developed for each region, state, census units, flood zones, coastal zones, etc. to achieve best results.) Besides, the present invention is “self-improving”—as new data points come in; regression curves become better for real-world prediction. Supported by massive data points, the statistical module comprises various regression equations such as Adjacent Grades & Floor Heights, Top-of-Slab & Floor Height, Top-of-Slab & Adjacent Grade, etc.

### S10.0 Elevations & Heights Module

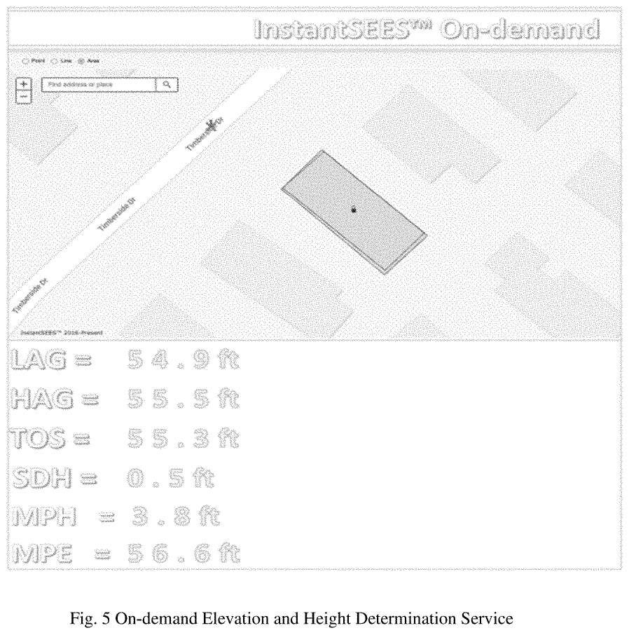

The present invention offers on-demand elevation determination and certification of structures and sites, as partly illustrated in FIG. 5, and performs various elevation-centric operations and analyses. Some of the products (such as elevations, heights, and derivatives) that the present system generates are listed below (some appears in FIG. 5.)

LAG: Lowest Adjacent Grade

HAG: Highest Adjacent Grade

TOS: Top-of-Slab Elevation

SDH: Height of Floor over Top of slab

MPH: Height at Measure Point

MPE: Elevation at Measure Point

FIT: Flood Impacting Threshold

FITS: Flood Impacting Threshold Score

FITS Elevation: Elevation of a FIT Event

FITS Frequency: Frequency of a FIT Event

WET: Water Entering Threshold

WSEL: Water Surface Elevation of a water event

Based on an elevation terrain model such as a Digital Elevation Model (DEM,) the present invention determines terrain elevation at a certain point location. Determining the elevation at a “measure point” is critical. If the height of a certain structure feature, say a door bottom, is available, then the elevation of this feature equals to the terrain elevation at the measuring point plus/minus the height. (e.g. adding 3.2 feet above terrain elevation of 180 ft yields 183.2 ft elevation for the bottom of a door. Subtracting 9 feet from 180 ft yields an elevation of 171 feet for the basement floor.) Height estimates come from various methods including direct user input or artificial intelligence—computer vision predictions.

The present invention also determines elevations along a line feature or a polygon's sides, such as a road segment and a building footprint. Then, the Lowest, Highest, and Median Adjacent Grades (LAG, HAG, and MAG) are calculated, which are key elevation characteristics of a structure or site. As illustrated in FIG. 5, typically, a user supplies inputs necessary for the system to locate the site or structure of interest. The inputs normally include address, coordinates, and clicking on a map or satellite imagery. The user does so through the Graphic User Interface and associated backend processes. The user can perform on-screen digitization to capture features' coordinates precisely (e.g. building footprint polygon, a measure point, etc.) and pass to the system. The coordinates are used by the system to construct geometry objects, or shapes, which are used to intersect with a terrain elevation model. The geometry objects are elevated and Lowest Adjacent Grade, Highest Adjacent Grade are calculated.

The present invention also determines various structure elevations and heights such as Floor Elevation, Floor Height, Top-of-Slab Elevation, Bottom of Door Height over Terrain, etc. Once the system pinpoints the building or site of interest, it acquires side-view photos and ortho imagery of the building. The images are fed into the AI-CV (Artificial Intelligence-Computer Vision) Module for processing, pre-trained for detecting various objects such as doors, garage doors, height objects and features, etc. The dimensions of the extracted objects of interest are then analyzed and compared with reference objects of known dimensions to determine the dimensions of objects of interest. This module also interacts with other modules, such as Z-reference, Observation-related, and Virtual Survey Modules.

The present invention offers a service for assessing comprehensively elevation characteristics on-demand on a national or global scale. These elevation and Height characteristics (LAG, HAG, feature elevation, floor elevation, feature height, floor height, Top-of-Slab Elevation, Floor-to-slab Height, etc.) are critical for various purposes including rating flood risk and insurance premium at the structure level.

### S11.0 Image & Imagery Analysis Module

The present invention uses various image analyses in its process detecting, extracting, determining, and analyzing structure characteristics. It uses various algorithms to extract features and objects from satellite imageries, aerial photos, pictures of structures and buildings, etc. Image analysis algorithms process an image by analyzing pixel-by-pixel variations of captured light and color to detect and extract patterns and edges. For example, it extracts building footprints, rooftops, and edges from ortho- or oblique imageries by using image analysis algorithms. Building footprint is an important building characteristic itself, and it is critical for determining other characteristics of a building, such as location of the building, shape of the building, area estimate, door and other locations, terrain elevations, Adjacent Grades, floor elevations, floor height, etc. Similarly, it extracts various objects such as forest land, lawn patches, paved surface, roads, driveway, sidewalk, water bodies and rivers, etc.

The present invention extracts features and objects from sideview photos of structures. It extracts features based on imagery analysis techniques such as edge detection. For example, it detects and extracts objects such as buildings, floors, doors, garage doors, open garage, windows, etc. The present invention assigns attributes to the extracted features such as building footprints, locations, coordinates, type of building, etc. The present invention further detects and extracts objects and features from an image by using multiple approaches complementary to each other. Image analysis is one, artificial intelligence-computer vision is another, which are based on machine-learning technology.

### S12.0 Observing and Sensing Module

To produce structure characteristics, the present invention utilizes data collected on-site through various hardware and software devices such as mobile electronic devices. These devices are ubiquitous today and the sensors they carry provide valuable information for determining and estimating structure characteristics. These sensors include GPS, barometric, accelerometer, camera, wi-fi unit, etc. All data collected can be processed on-device and on-site, transmitted to another machine for processing remotely, or both.

The present invention provides mechanisms and interfaces to allow users to activate camera on a mobile device, take a photo, and transmit the picture for processing along with other data and metadata (e.g. camera settings, GPS readings, etc.) Today This is a big deal because most of the time, there is either no picture of the structure of interest available, or the picture quality is poor, or obsolete. To allow users take and upload their own pictures solves the biggest hurdle for determining structure characteristics: obtaining observation data. The present inventions also collect key data and metadata about the images utilized, such as camera settings, GPS locations, etc. It also provides mechanisms for a user, picture taker, or uploader to provide extra information about the image before it is sent for processing. These “extra” information includes markup on the images, labeling, bounding boxes, objects, known objects of known dimensions on image, assigning location, attributes whatever applicable on the image, etc. For example, a user can pre-position a “human/machine recognizable” reference object of known dimensions (e.g. a ruler or a piece of printing paper) in the picture frame to make other elements of the picture accurately measurable. The prediction results based on such an image usually produce more reliable and accurate results.

The present invention uses GPS sensors to directly acquire coordinates of the device at a specific time. These coordinates are vital for determining various data points such as viewpoint location and camera location, which are key metadata for data produced by the device. For example, the present invention utilizes a structure's pictures taken and uploaded directly from a mobile device. The location data and other metadata of the image (e.g. camera settings) are also sent to the system along with the image itself for processing.

As detailed in the present inventors' U.S. patent application Ser. No. 15/839,928, filed Dec. 13, 2017 now U.S. Pat. No. 11,107,025 issued on Aug. 31, 2021, the present invention utilizes barometric sensors on a mobile device to estimate absolute elevations or the difference (i.e., height) between two measured levels. It performs this elevation estimates on-site, outdoors, or indoors. For example, a user can first lay his phone on the ground and let the system take a reading of barometer. Then he raises the device to the level where the picture is taken, and the system takes another reading of the barometer. Based on the two readings, the vertical difference of the two camera positions can be estimated. Combining with the elevation at the camera location, it predicts the elevation level of the camera.

Similarly, the present inventions measure elevation differences and height on-site by using accelerometer on-device. Accelerometers not only can calculate shifts in both horizontal and vertical directions, but it also provides key metadata for any image the system uses, including the angle and facing direction of the camera. The present invention uses LIDAR sensors to directly measure distances from a device and another object and feature. It can collect data from other sensors on a mobile device, including humidity detector, thermometer, etc. These sensors provide data that can be directly or indirectly utilized by the system to generate results.

### S13.0 Certification Module

The present invention includes various mechanisms and processes to ensure credibility and reliability of its information products. In this application, we refer to them as the Certification Process. It performs certain “judgmental actions” on the data produced, including verification, rejection or acceptance, correct or false, adjustment, etc. It produces reliable and certified data products and reports such as elevation certificates.

FIG. 3 illustrates one of the present invention's Elevation Certification processes as one embodiment of the Certification Process. Numbered sub-processes in FIG. 3 and their corresponding main functions are listed below:

f3.1: Fully Automated Elevation Process

f3.2: Generating products, including various heights and elevations (H&E)

f3.3: Present and deliver automatically generated results

f3.4: Actions performed by users, such as Verify, Accept, Approve, Sign, Certify, Reject, Adjust, etc.

f3.5: Present and deliver SELF-CERTIFIED products

f3.6: User-aided Certification Process

f3.7: Generating products, such as various heights and elevations, with assistance from user

f3.8: Actions performed by users, such as Verify, Accept, Approve, Sign, Certify, Reject, Adjust, etc.

f3.9: Professional Certification Process involving specialists

f3.10: Generating products, such as various heights and elevations, with assistance from users

f3.11: Actions performed by users, such as Verify, Accept, Approve, Sign, Certify, Reject, Adjust, etc.

f3.12: Present and deliver PROFESSIONALLY CERTIFIED products

The present invention produces its information products in various ways including automated production with minimum amount of user inputs and interaction, user-aided certification by providing extra inputs and human judgement and involving professional assistance from a specialist (other than the user.) It produces fully automated and machine-generated products, user self-certified products, and professionally certified products.

For the Fully Automated process, as depicted in FIGS. 3—f3.1, the system generates results based on minimum user inputs. The minimum inputs comprise critical information such as that for the system to sufficiently locate a building or site of interest; often it is a building or building footprint identifier, a location descriptor (e.g. mailing address, intersection, etc.) to be converted to real-word coordinates, or directly coordinates of a building or site of interest. The present invention provides mechanisms and tools for the users to interact with a map control by clicking or tapping, convert screen-coordinates to real-world coordinates (e.g. latitude and longitude, etc.), and pass the coordinates of the building or site of interest to the backend processes. Next, as depicted in FIG. 3, f3.2 and based on the coordinates, the system produces various products such as heights and elevations (H&E) and present the results to requesters (FIG. 3, f3.3.) This is the most cost-effective and time-saving option; the system automatically determines the rest of all necessary inputs (e.g. location of interest, building type, foundation type, side-view image of building, object and features' locations, building footprints, etc.) The fully automated results can be directly utilized for various purposes including rating flood risk. The system offers users further options to pass certain judgements regarding the results; such options allow users to verify, accept, approve, sign, certify, reject, adjust, etc. (FIG. 3, f3.4.) If the user chooses to “SELF CERTIFY” the result, the system then produces a CERTIFICATE accordingly (FIG. 3, f3.5.) From here, if user desires to acquire an even better report, a professionally certified one, the system offers the option for the user to request such a service, as depicted in FIGS. 3—f3.9. If the user wants to rerun the model for new or better results by providing extra inputs to the system, the present invention will start user-aided workflow (FIG. 3, f3.6)

Sometimes the system does not produce good-enough results due to various reasons including no observation data available, poor observation data, wrong user inputs, poor quality, etc. Without producing information in a reliable fashion, the product or data service would be of no practical value. To solve this challenge, as depicted in FIG. 3, f3.6 and f3.7, the present invention allows users to provide extra inputs and judgement to be used by the system to generate better results more reliably and accurately. For example, in case of no observation or poor observation data, the system allows users to take a good-quality picture directly from a mobile device and upload that picture, along with camera settings and GPS readings, to the system for processing. Users can also provide a picture with a pre-positioned object of human/machine-detectable pattern and known dimensions, based on which making predictions and measurement become much more accurate and reliable. The system is pre-trained to recognize and extract that object. As an example, currently the system's AI-CV Module is pre-trained for a ubiquitous and standard printing paper taped on the front door. The paper's known dimensions, say 8 by 10 inches, are used to calculate dimensions of other objects in the picture, such as the door and the height between the bottom of the door and underlying terrain. The present invention can also further interact with users and accept other inputs such as an URL for accessing a remote image (source,) on-screen digitized results (e.g. locations, geometries, objects, features), and markup on a picture, labeling (e.g. bounding shapes of objects, bounding boxes, etc.) on an image, creating new or adjusting auto-generated objects' shape, size, and position (e.g. a building footprint polygon, a bounding box of a door, a height object, etc.) to improve accuracy, correct errors, adjusting locations, clicking on a geo-referenced map or imagery to indicate accurate locations of features and objects, etc. Because users are on-site and know the building the best, they can provide accurate measurements, locations, and other estimates such as various heights (basement height, floor height, etc.), precise locations, etc. Information of building characteristics is also among such valuable inputs, including that regarding basement, garage, elevated or not, foundation type, etc. As depicted in FIG. 3, f3.7 as part of the system workflow, these “extra” inputs play a critical role for generating products of greater accuracy and reliability.

As depicted in FIGS. 3, f3.4, f3.5, f3.8, f3.11 and f3.12, the present invention offers mechanisms for a user to apply human judgement against the information generated, especially the end-products, by performing certain actions such as verification, rejection, acceptance, approval, correction, certification, signing, etc. regarding the results produced by the system. For example, it offers features and tools for users to verify results such as the location of an object on map, a picture of the building of interest, the height below a door over terrain, etc. The present invention offers features and tools for user to indicate acceptance or rejection of the result, adjust model parameters accordingly, and re-run the model until favorable results are generated. Then it allows the user to “self-certify” the result. In case of determining structure elevations or heights, for example, the user such as a homeowner knows his or her property the best and can verify and certify with high confidence. In case the result is not accepted, the user can provide extra valuable inputs and certain judgement to rerun predicting models to ensure much greater reliability of the products. The “results of the User Aided Process” can be delivered as-is, self-certified, or re-run until satisfaction. To produce accurate, credible, and reliable results, the present invention provides features and tools for requesting another human being, besides the user, to aid the process as depicted in FIGS. 3, f3.9 and f3.10. It can be a specialist, a professional, a certified professional, or any person trained for the job. In need of best products, a user requests such type of assistance and service by picking an element on the user interface, and the system will engage and arrange accordingly. A trained specialist can select the best inputs for prediction modeling, best modeling methods, and most reliable judgement toward the results. The specialist can function alone or utilize materials user provides previously (e.g. extra inputs such as photos of the building) and optionally interact with the requester. He or she can also directly interact with a user during this stage.

The present invention offers mechanisms to certify the information produced. Users can “self-certify by signing” and professionals can certify the information by signing. For many purposes, “self-certified” (elevation) certificates are sufficient; a user can simply look at the product along with other supporting information provided and acknowledge his or her acceptance. This “human-aided” process would avoid obvious errors to ensure certain level of accuracy and reliability. In case of structure height, for example, a homeowner would be able to easily verify that his house is elevated X feet above ground and compare with the system predicted results. He self-certifies it and the certificate can then be used by mortgage lenders or insurers with greater confidence regarding the accuracy of the data. The requester of the certificate would not “self-certify” if he rejects the result based on what he knows or sees. For many other purposes, such as underwriting insurance policies, the system can produce professionally certified results. The professionals have “trained eyes” and can generate and guarantee the reliability and accuracy of information produced (FIGS. 3, f3.11 and f3.12.) The present invention includes both user interfaces and backend processes for self- or professionally certification. The present invention comprises features for signing, saving relevant artifacts, and printing the certificate.

The present invention produces a digital certificate of structures, such as an elevation certificate. It can take various forms and formats such as a PDF, an IMAGE, XML, or Microsoft Word file. It has various relevant information including addresses, location information, parcel information, etc. The certificate contains various relevant information of structure characteristics such as addresses, coordinates, picture of a side of the building, ortho-image of the structure or the area of interest, the drawing of building footprints, drawing of a building, etc. Once a reference level of elevation is determined, the present invention marks the reference level on a picture, which can be used for communication purposes. (e.g. an arrow marking the bottom of the door and with labels similar to “398 ft above sea level” are used in elevation certificate.) The present invention produces a picture of the structure with labels and markups, indicating one or more reference elevation, such as water surface elevation of certain flooding events, and floor or door elevation of the building. The present invention is a great way to communicate flooding risk quickly nation-wide, and on-demand. Such a certificate includes various information including structure elevation, First Floor Elevation, terrain elevation, structure height, object height, Height of a door bottom above underlying terrain, First Floor Height, top of a floor/structure/object, bottom, garage, slab, equipment, lowest adjacent grade, highest adjacent grade, stairs, Lowest Floor Elevation (LFE), top of next higher floor, etc. The present invention allows users to print hardcopies of the certificate based on the digital version.

Elevation Certificate Process is critical for many businesses especially for flood insurance industry. U.S. Federal Emergency Management Agency (FEMA)'s Elevation Certificate process powers the entire flood insurance industry for decades. Mortgage lenders and insurers relies on it to conduct day-to-day business. And property owners bear the cost. The present invention greatly lowers the cost of obtaining such certificates from hundreds even thousands of dollars per certificate. It also greatly shortens the duration to fulfill such a certification; it cuts the duration from weeks or days to just minute or even seconds. The self-certification process alone, for example, of the present system is of great practical value; a seemingly simple technique, once combined with technology and integrated into a well-defined defined process, it becomes powerful and revolutionary. The present invention combines “human intelligence” with “machine intelligence” to achieve the best result. Insofar as we know, no one else has offered such a practical “elevation certification” process that is on-demand, rapid, massive scale, reliable, and low cost.

### S14.0 AI & CV Module

The present invention includes an Artificial Intelligence (AI)-Computer Vision (CV) Module (AI-CV Module.) Based on observation data (e.g. imageries, photos, ortho-satellite imagery, sideview photo of building, etc.) it automatically detects objects or features, extracts coordinate of objects and features, predicts characteristics of building or site, measures dimensions of objects or features, analyzes such information, and generates various products. This module's core models are built upon AI's machine-learning technologies such as convolutional neural networks and region-based convolutional neural networks. The implementation is based on technologies, code libraries, and frameworks such as TensorFlow. The models, before ready for prediction, are “trained” through a training process, during which images are labeled, marked up, and fed into the system so that the machine can learn. This training process requires a large number of labeled images, and the information of labels and objects are organized and captured in a structured format such as XML format. The information then passed into various “models” for automatic training and learning. When the models reach certain satisfactory level, they will be deployed to go live for processing incoming requests. The present invention builds AI-CV models by training using labeled images including satellite ortho-imagery, oblique imagery, sideview photos of a structure, photos, and pictures. The resulted models process “unknown” images to detect and extract various features and objects such as a door.

For example, the present invention comprises trained models for automated detection and extraction of buildings, doors, stairs, building footprints from imagery, manmade structure or surface, walkway, driveway, etc., in supplied or requested images. These models are trained by massive amount of “labeled images,” telling the machine what a human being sees in the picture. The present invention detects and extracts rooftop and building footprints from imagery and the resulted coordinates are geo-referenced. Similarly based on imagery “from the above” it detects various surfaces including waters, paved roads, driveway, sidewalks, lawns, forests, etc. The module can extract the bounding box (rectangles or squares) of an object/feature in the image, or it can extract the actual shape of the feature or object on the image by extracting vertices defining that shape. The extracted objects are captured in coordinates stored in a certain data structure.

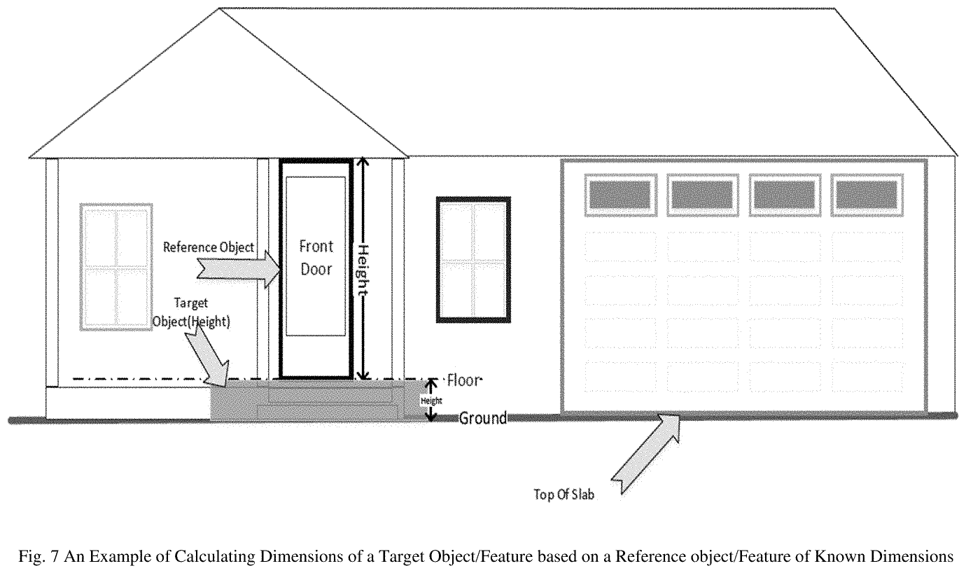

For determining structure characteristics, the present invention utilizes both side-view photos of a building and “above-view” imageries (such as ortho and oblique imagery.). Based on a side-view of a building, the AI-CV Module detects and extracts various objects and features of a structure of interest. Examples of such detection and extraction include doors, windows, stories, roof, side of a building, building outlines, etc. The present invention detects objects and features in an image such as one acquired from Google StreetView, or one uploaded by a user, and extracts the objects of interest with coordinates relative to the picture. Critical to elevation and height measurement, the AI-CV module extract special Height Objects, such as one defining the height between the bottom of the door and the underlying terrain. (One such a special Height Object is illustrated as the Target Object in FIG. 7)

Among the objects and features detected and extracted, some are of known or pre-determined dimensions, such as 80-inch-tall doors. They are of critical significance in the process of determining structure elevation and other related characteristics. In FIG. 7, a Reference Object of known dimensions is used to measure the dimensions of the Target Object. when an extracted door's dimension and position are known or determined, and expressed as coordinates, other objects or features on the image become measurable. One simple scenario: an 80-inch door is detected in the picture and extracted by the system as 80 pixels high. Below the door and in the same vertical plain, another rectangular height object of 20 pixels tall is detected and extracted, representing the height between the bottom of the door the underlying terrain. It is simple math to calculate the actual height of the second object is 20 inches. Based on detected objects of known dimensions, the present invention calculates unknown dimensions of another object. (Previously, we call this method: P2H2E method.) The AI-CV module automatically extracts a door from a side-view image of a building, which is 100 pixels tall in the image. And we know that door is 80 inches tall in real world. The model also detects and extracts another object, say a window that is 50 pixels tall in the image. We want to know how tall the window is in the real world. Then the window's height H=80 inches×50 pixels/100 pixels=40 inches.

Detecting and extracting objects and features of known dimensions and use them to measure objects and features of unknown dimensions in the picture is one of the most valuable assets of the present invention. It is critical for various purposes including calculating heights and elevations such as that between the bottom of a door and the underlying terrain, and ultimately the absolute elevations of structure. This height and elevation are critical data points for rating flood risks and estimating insurance premium. This method, fully implemented in the present invention and in an on-demand fashion, is of great practical value!

The AI-CV technology makes the above “simple math” extremely powerful because it detects objects automatically. It can determine and estimate floor height at the door, for example, which is critical for rating flood insurance and for planning emergency responses. The AI-CV models greatly lowers the duration and cost, by increasing the speed and automation of the process. Similar to detecting and extracting objects and features in a sideview image, the present invention detects, extracts, and measures objects and features on a “above view” image such as ortho and oblique imagery.

For example, the present invention comprises AI-CV models for detecting and extracting valuable building characteristics such as building footprints and rooftops on-the-fly, along with other features and objects such as paved surfaces, driveway, road surface, sidewalks, lawns, forests, etc. The present invention can combine the above-mentioned information to generate new information products that is unprecedented. For example, the present invention produces elevation of top-of-slab (also illustrated in FIG. 7 as the bottom of the garage door) of a building by assigning terrain elevation at the intersection of the extracted building footprint and driveway in an ortho-image. This Top-of-Slab Elevation is a key piece of information on an Elevation Certificate which is critical for rating flood risks and insurance premium.

### S15.0 Observation, Analytical, and Management Module

The preset invention determines structure characteristics through various methods; one of the preferred is observation-based approach. AI-CV module determines structure characteristics by using machines “look” at a picture, detect, and extract information, objects, features, and analytics. For example, it identifies building roof tops in ortho-imagery and doors in a side-view picture of a building. Statistical Module include regression equations that is developed based on massive amounts of data points in various forms; majority of the data points are extracted or derived from observation.

The acquisition of observation data is critical and usually is one of the biggest cost items in the overall process. Side-view of structures, for example, are acquired from providers such as Google StreetView API, but often the provided service does not cover area of interests in the US and around the world. Even if a service provides some photos of the structure of interest, the quality of the photos is often not good enough for the determination of structure characteristics. The present invention solves this problem by various approaches including providing mechanisms allowing a user take and upload their own pictures of the structure of interest. This is a big and practical invention making observation-based determination of structure characteristics possible anywhere without troubling users much; all those users are required to do is to take a picture using a mobile device and submitted it for local or remote processing of the picture. (In a real-world scenario, this simple yet powerful invention forms one of the pillars of our “Certification Module,” illustrated in FIG. 3, which generates reliable and accurate certificates based on observation.

The present invention acquires observation data in various ways including through a specified data source, image source, data feed, API calling (e.g. Google, Bing, Apple, ESRI, etc.) direct user taking a picture, user uploading. Besides observation data, the present invention acquires metadata about observation such as image source, service address, data feed, etc. It activates sensors on devices to acquire readings of the observation and its surrounding environment. The present invention also provides mechanisms for a user to draw and mark up on the observation, indicating the position or location of an object, an object/feature of interest, a “known” object, an object of known dimensions, or any indicators direct human or machine to process, etc. More specifically, the present invention allows users to indicate where the “terrain line” is in a “side-view” of a picture, or where a door is, the geometry bounding a door, a house, or any other objects or features, slab line of a building, piling of a building, etc. The present invention allows users to manipulate an object of interest on a device. For example, it allows users to place, adjust, resize, digitize, attribute objects on a device's screen (e.g. bounding boxes and on-screen digitized geometries.) It can perform this in a web browsers window, or through a camera's “live view”, ARVR window, on a device's screen. The on-device AI-CV module puts bounding shapes on or around objects and features of interests (e.g. in live view of the house, the AI draws the bounding box of doors and windows.) Users or specialist can directly manipulate such machine-generated objects.

The present invention has various ways to pre-position a known object, or an object of KNOWN dimensions in a picture/image before it is taken; the object would be used as a “reference object” for calculating dimensions of other objects, features, or performing measurements on the picture or image. For example, it instructs a user to include an object of known dimensions as part of the picture he is taking. The picture-taker can simply tape a piece of 10×8″ printing paper, which has unique shape and color on the door or the wall of the house before taking the picture. The AI-CV module contains various models that are pre-trained on such objects or features. The AI-CV Module detects and extracts in the picture such an object with high accuracy and use it to calculate dimensions of other objects or features, such as a height object in real-world units. This “object of known dimensions” in the picture can be pre-positioned before the picture is taken, or after the picture is taken. The object can be a physical object, like a piece of paper, or a virtual object overlaid on the picture.

The present invention processes videos to identify and extract objects and features. Each frame of the video has timestamp on it, which is used to extract location of the camera along with other camera settings including headings and angles of the lens. The rest of the processing is similar to with processing a single picture. This invention is key for vehicle-based image acquisition of roadside features, such as houses, doors, windows, etc. The present invention determines structure characteristics based on user taken and/or uploaded pictures, which significantly simplifies the overall process. Similarly, it pre-positions a known object of known dimensions in the picture, before or after the picture is taken.

### S16.0 Z-Reference Module

This module comprises various algorithms and processes for setting vertical references (Z-references) for a structure or for a structure's image. It calculates various elevations by referring to this vertical datum. For examples, adding a height on top of this vertical datum of a structure would generate the feature's elevation (above sea level.) The present invention determines elevation of garage's floor (a.k.a. Top-of-Slab, bottom of garage door, or bottom of an open garage) and set it as a vertical datum of the structure. Based on ortho imagery, it does so by first determining the location of the garage, or its complete or partial boundary, by means such as detecting the building footprint and driveway first, extracting and intersect them, determining terrain elevation at the intersection (where part of the boundary of garage slab is), and assigning the terrain reading as the floor reading of the garage. (This locating process can be performed automatically by a ‘intelligent machine” or by a person by directly specifying such locations by interacting with a geo-referenced screen like a map or imagery.) Based on this vertical reference, adding or subtracting a height would result in other structure elevations. (For example, the elevation of top of the slab is 100 feet above sea level, and the first floor is 3 feet above the slab, then the elevation of the first floor is 103 feet above sea level. Similarly, if a basement floor is 6 feet below the slab, the elevation of the basement floor would be 94 feet above sea level. Such height s can be determined through various means including statistical methods such as direct user inputs or a prediction based on regression equation between heights and slabs for a geographic area or group.) This ingenious translation of terrain elevation to a vertical datum is based on the insight that at the intersection, the terrain elevation equals to slab elevation of the garage. This invention is a game-changer because the current invention can automatically (or manually) and reliably figure out the intersection based on ortho imagery or side-view image of a structure, precisely read the underlying terrain elevation model, and generate the most reliable elevation reference of a building.

As an example, on an ortho-image or map, its AI module specifies and extracts two features, such as building footprint polygon and road connecting to the building. The elevation of the intersection represents where the terrain elevation equals to the structure location, a key structure elevation reference. The present invention reads the DEM at the intersection, assigns the reading to the garage slab of the building. By determining the difference between a feature and the above vertical difference, other features' elevations can be determined. (Feature Elevation=Vertical Datum+Height) For example, the garage floor's elevation (Top-of-slab) is 198 ft, and the first floor is 2 feet above the slab, then the First Floor Elevation is 200 ft (above sea level.)

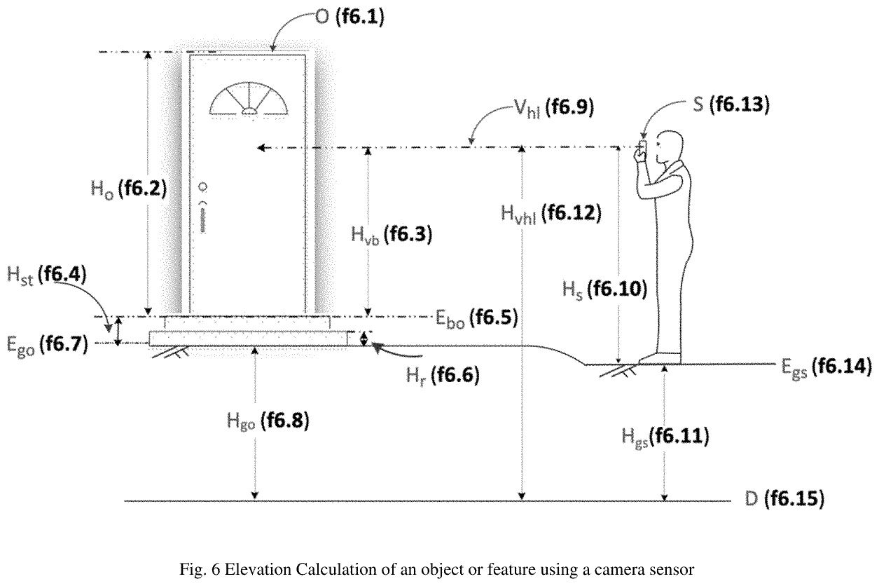

The present invention also sets vertical reference points on a side-view image of a building, based on which elevation or height of features and objects on the image are calculated. As illustrated in FIG. 6, the present invention determines the “principal point” on an image where its elevation equals to the elevation of the center of the camera lens. If the camera setting (e.g. height and angle of the view) is known, and the “principal point” of such a side-view picture is also known (e.g. the principal point is the center of the image) at where the real-world elevation for that point equals to the camera height at the viewpoint plus the underlying terrain elevation. The camera height can be determined from camera settings, user inputs, direct measurement, etc. The present invention transfers the elevation of camera's lens (camera height) to a feature (e.g. a pixel, a point) on image (e.g. center of image). From this elevation reference point, other pixels' elevation can be calculated. Combined with height measuring, specified in VirtualSurvey Module, and distance between camera and the structure of interest, from this elevation reference, the elevation of other pixels and features are calculated.

Referring to FIG. 6, the above process is described in further detail. The elevation of an earth feature or object is its height above a vertical datum D (FIG. 6, f6.15) that is a reference surface for vertical positions. Object height Hvb (FIG. 6, f6.3) is defined as the height measured from the bottom of the object O (FIG. 6, f6.1) to the horizon line of the sensor's viewpoint Vₕₗ (FIG. 6, f6.9). Object height H_{vb} (FIG. 6, f6.3) can be calculated by estimating the proportion of the H_{vb} (FIG. 6, f6.3) from the front door height Hₒ (FIG. 6, f6.2). If object height Hₒ (FIG. 6, f6.2) is unknown, object height Hₒ (FIG. 6, f6.2) can be also determined from a near-by object of a known dimension in the same plane as the object. The H_{vb} (FIG. 6, f6.3) in the figure is about two-thirds of the front door height Hₒ (FIG. 6, f6.2), expressed as ⅔* Hₒ (FIG. 6, f6.2).

Object elevation is defined as the height measured from the vertical datum D (FIG. 6, f6.15) to any parts of the object such as bottom of the object, top of the object. Elevation of the bottom of the object Ebo (FIG. 6, f6.5) can be calculated by subtracting H_{vb} (FIG. 6, f6.3) from the elevation of VIA (FIG. 6, f6.9) defined as Hᵥₕₗ (FIG. 6, f6.12), where Hᵥₕₗ (FIG. 6, f6.12) can be computed by adding the height of the sensor Hₛ (FIG. 6, f6.10) to the height of ground at the location of sensor H_{gs} (FIG. 6, f6.11), measured from D (FIG. 6, f6.15). The height H_{gs} (FIG. 6, f6.11) is equal to the elevation E_{gs} (FIG. 6, f6.14.) Elevation of a feature or object can be directly measured using various devices such as smart phones equipped with sensors that can measure altitude, or indirectly measured with GPS devices and GPS-enabled devices such as smart phones that provide geographic location and elevation services such as google maps.

The geographical location of the sensor S (FIG. 6, f6.13) can defined by a geographic coordinate system that is a method for determining the position of a geographic location on the earth's surface as a three-dimensional spherical surface using the latitude, longitude and elevation. The geographic location represented as coordinates of the sensor S (FIG. 6, f6.13) can be determined by various devices such as GPS devices, GPS-enabled camera, smart-phones assisted with various applications such as google maps. The ground elevation at the sensor E_{gs} (FIG. 6, f6.14) can be determined using various methods; determined using various devices such as smart phones equipped with sensors to measure altitude; determined using various devices that provide elevation services such as USGS national map viewer, ESRI world elevation services, and google elevation maps or APIs at a given geographic location determined from various GPS or GPS-enabled devices; determined using various devices such as GPS-enabled smart phones that provide both geographic location and elevation services such as google earth, google location and elevation maps or APIs.

The height of the sensor Hₛ (FIG. 6, f6.10) is defined as the height measured from the ground with which the sensor's gravity line intersects to the geographical location of the sensor. Sensor's height Hₛ (FIG. 6, f6.10) can be derived from a known height such as human's height minus the height measured between human's eye and top of head or can be directly obtained from settings or specifications such as a camera height mounted on top of vehicle. The elevation of the bottom of object Ebo (FIG. 6, f6.5) can also be calculated by adding stair height Hₛₜ (FIG. 6, f6.4) to ground elevation at the object E_{go} (FIG. 6, f6.7). The ground elevation at the object E_{go} (FIG. 6, f6.7) can be calculated using various methods to determine geographic location and elevation of an object or feature such as a method that utilizes ortho-view map services such as google maps to visually identify the location of the object O (FIG. 6, f6.1) and click on the map to get the geographic coordinates and then utilizes elevation services such as google elevation map or API that are available in various devices such as smart phones to get the elevation at the given geographic coordinates of the object O (FIG. 6, f6.1).

The height of the stair Hₛₜ (FIG. 6, f6.4) can be calculated by multiplying the number of stair risers by riser height of the stair Hᵣ (FIG. 6, f6.6) that is between 7 and “7 plus ¾” inches at the most. The ground elevation at the object E_{go} (FIG. 6, f6.7) can be also calculated by using a formula:

$$\begin{matrix}{E}_{go} = {H}_{vhl} - {H}_{vb} - {H}_{st} \\ = {H}_{vhl} - {H}_{vb} - ( \# stair risers ) * {H}_{r}\end{matrix}$$

The present invention calculates “real-world Unit Per Pixel” (UPP) on a picture based on measurable features and objects in the picture, objects and features of known dimensions, various camera settings and positions, distance between the camera and subject, or correlations between UPP and other parameters, such as the distance between a subject in the picture. Once UPP is set for a picture, elements in the picture becomes measurable. For example, a door that is 80 inches tall in real world is 80 pixels tall in the picture. The (vertical) UPP of the picture then is 1 inch per pixel. If the height of the building, in the same plain of the door, is 240 pixels tall, based on the UPP, the height of the building in real world would be 240 inches. Once a vertical reference level is determined, the present invention marks the reference level on a picture, which can be used for communication purposes. For example, an arrow marking the bottom of the door and with labels similar to “398 ft above sea level” are used in Elevation Certificate.

### S17.0 VirtualSurvey Module

Conducting on-site survey is expensive and time-consuming. For example, to obtain an Elevation Certificate that is required for mortgage application or flood insurance purchasing, home buyer needs to schedule in advance, wait for days even weeks before surveyors show up, and pay hundreds of dollars.

This is one of the biggest hurdles impeding many relevant business processes such as mortgage application, insurance rating, flood insurance purchasing, etc. The present invention solves this by conducting surveys virtually, remotely, and on-demand. Based on a detected object of known dimensions in a picture, the present invention calculates unknown dimensions of other objects, features or elements of the pictures. (Internally, we call this method: P2H2E method.)

For example, a human or a machine detects and extracts a door from a side-view image of a building, which is 100 pixels tall in the image. And we know that door is 80 inches tall in real world. The human or the machine also detects and extracts another object, say a window that is 50 pixels tall in the image and they are in the same vertical plain. We want to know how tall the window is in the real world. Then the window's height H is calculated as: 80 inches×50 pixels/100 pixels =40 inches.

The present invention makes the above “simple math” extremely powerful because it detects objects automatically and can generate dimensions that are valuable. It provides tools to facilitate “a human plus machine” process in which a human aid a machine process and vice versa. It can determine and estimate floor height at the door, for example, which is critical for rating flood insurance and for planning emergency responses. The present invention greatly lowers the duration and cost, by increasing the speed and automation of the process.

The present invention “measures” height objects/feature this way, such as deck height, floor height, stair height, door height, etc. Adding the calculated height of an object/feature to the underlying DEM reading would generate “absolute” elevation for the feature. For example, if the exact location of the door is known, the bottom of a door of a building is 3 feet above the underlying terrain, which 298 feet above sea level. So, the “absolute” elevation of the bottom of the door is 301 feet above sea level. Similarly, if the basement floor of a house is 10 feet below the door bottom mentioned above, then the base floor is 292 feet above sea level (298+3−10=292 ft.) Similarly, the present invention measures or calculates distances horizontally, vertically, or any direction.

The VirtualSurvey Module provides various tools to facilitate the process. One of the tools assists staff members to locate survey targets (e.g. a residential building), request various observation data from various sources (e.g. images of target from Google StreetView,) capturing and saving various information about the target (e.g. building type, single family, no basement, etc.), identifying objects and features (e.g. deck position, door bottom, deck height, etc.) drawing/labeling and attributing objects by on-screen digitization (e.g. door, stairs, 72 inches, etc.), indicating which part of the image to process (e.g. top of pilings of an elevated home as measurement), the image saving somewhere (e.g. to cloud storage), and uploading information for further processing. It allows either users or a professional to identify features or objects on the image. It does so by allow users to “draw and digitize” on the pictures, imagery, maps on the screen by using various shapes such as points, lines, polygons, circles, bounding boxes, etc. It also allows users of the tools to adjust, resize, move, attribute, re-attribute, the drawings. These tools are critical for any human-involved processes included in the present invention. Without them, the processes would remain laborious and costly and lacking practical values and scale.

### S18.0 Derivative, Visualization, and Product Module

The present invention produces various derivative products based on building characteristics and other relevant information. They are critical for various business processes and purposes. For example, the process of rating flood risk for a building and calculating flood insurance premium requires Floor Elevations, floor heights, basement information, garage floor elevation, top-of-slab elevation, foundation type, etc. of the structure. It is costly to acquire elevation characteristics of a location, a property, or a structure; one needs to contract a professional land surveyor and pay hundreds even thousands of dollars to obtain an “elevation certificate.” The present invention produces data on-demand, greatly expedite relevant business processes, and greatly lowered the cost for acquiring such data.

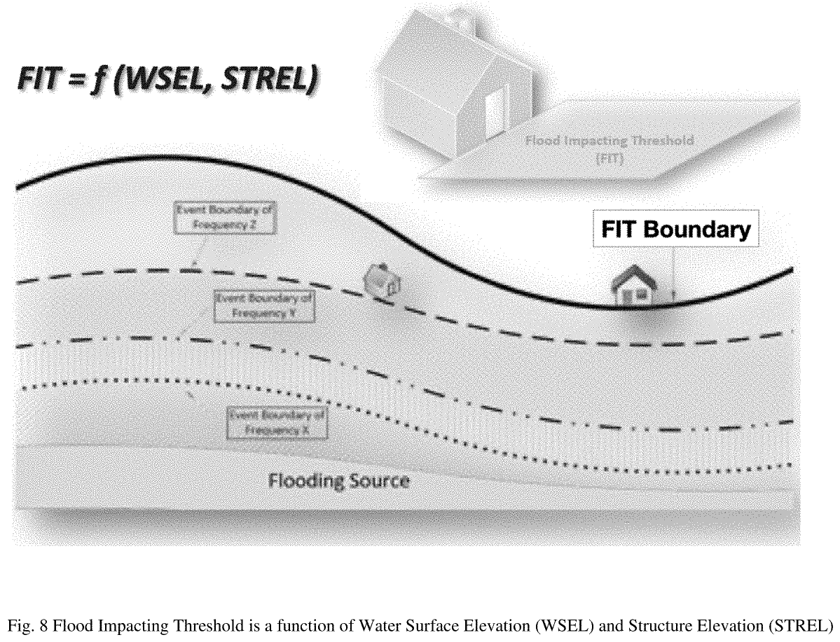

By accurately and timely predicting structure elevation and other characteristics of a structure or site, the present invention enables the generation of various valuable products. The present invention produces Flood Impacting Threshold Scores (FITS) based on the concept and means of Flood Impacting Threshold (FIT) of a structure or site, as described in the U.S. patent application Ser. No. 15/839,928, filed 12/13/2017, now U.S. Pat. No. 11,107,025. As illustrated in FIG. 8, it is a threshold event for a building or site when excessive water surface elevation just “touches” the building but not yet entering the building or causing any impact yet. It marks zero flood impact for the building or site. Flood Impacting Threshold (FIT) is property of the structure, independent of human judgement, and exists universally and globally. FIT depicts the progressive nature of flooding water and flood risk, breaking out from the conventional zone-based “in or out” paradigms. It precisely, fully, and consistently rates flood risk and differentiates flood risks building-to-building, with great sensitivity and comparability. Rather than describing a building is “IN” a 100-year floodplain with BFE 256 feet, for instance, now we say the building is “AT/ON” the line of 79-year FITS frequency with FITS elevation 254 feet. The above-mentioned concepts, products, and technologies are mature and available on massive scales. They are new and powerful tools for better accomplishing our mission: differentiate and communicate risk precisely, consistently, and at the building level.

The present invention determines Flood Impacting Threshold (FIT) based on two critical factors: Water Surface Elevation (WSEL) and Structure Elevation (STREL).

FIT=f(WSEL, STREL)

In determining FIT of a site or a structure, one key step is to model water surface elevations of, which is a commonly practiced engineering process. The present invention determines structure elevations, which is critical for the adoption of the FIT concept (shown in FIG. 8.) For example, the present invention accurately and consistently determines FIT, based on an assumption that water-entering the building through a door; in this case, the threshold event happens when water reaches the bottom of that door.) Water Entry Threshold (WET) is a specific type of Flood Impacting Threshold when water starts to “enter a structure or a building.” A WET elevation can be different from the lowest floor elevation of a structure, such as basement floor, or the elevation of a door. If water level is below the WET elevation, water depth in the structure is theoretically zero. If it is above, the water depth would jump from 0 to this level, assuming water fills the elevation difference (e.g. the entire basement) totally. To determine WET elevation, similar to FIT determination, two steps are required: Step 1 is to determine the part of the structure where water would first enter the building; examples include a door, a window, a ventilation opening, etc. Step 2 is to determine the lowest elevation produced from Step 1 above. WET Elevation equals the result of Step 2.

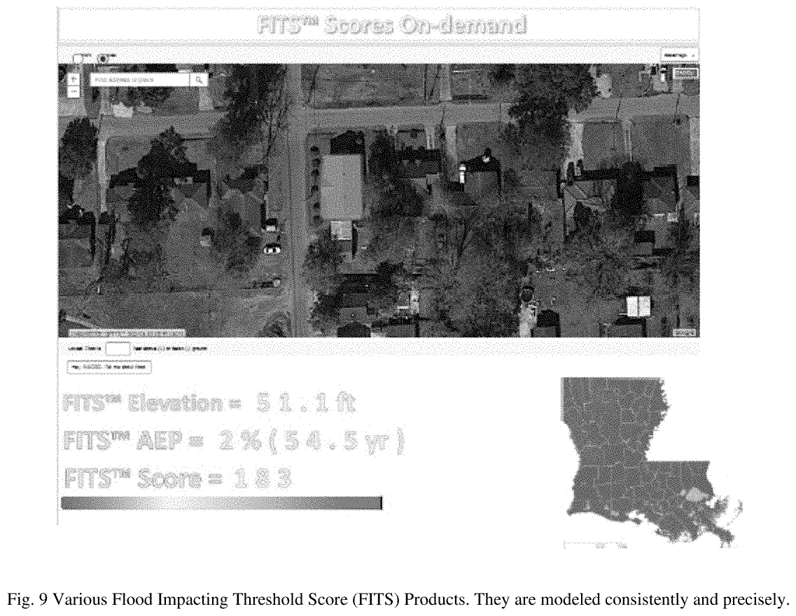

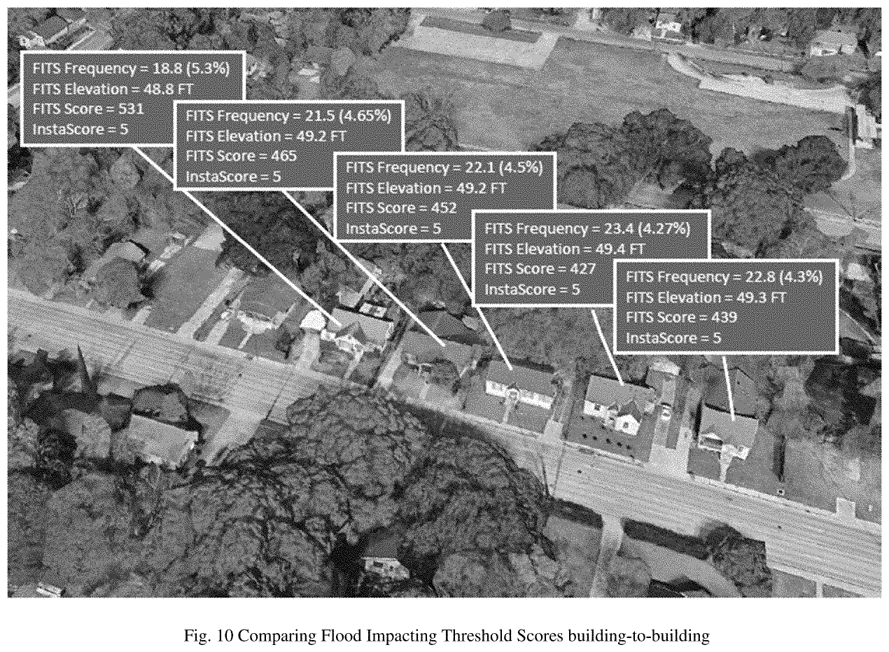

Once FIT is determined, the present invention produces various FITS products and scores relevant to the threshold event. These innovative products, some are illustrated in FIG. 9, include FITS (Water Surface) Elevation, FITS Frequency, FITS AEP (Annual Exceedance Probability, e.g. 5.3%), FITS Return Period (e.g. 18.8 year), etc. Because of its continuous and progressive nature, these FITS scores can precisely describe the risk levels at specific building level and are great for comparison globally and building-to-building as shown in FIG. 10. The present invention creates various products by aggregating various FITS products into certain groups, for example a community or neighborhood. Also, the present invention creates contour of FITS scores of individual buildings.

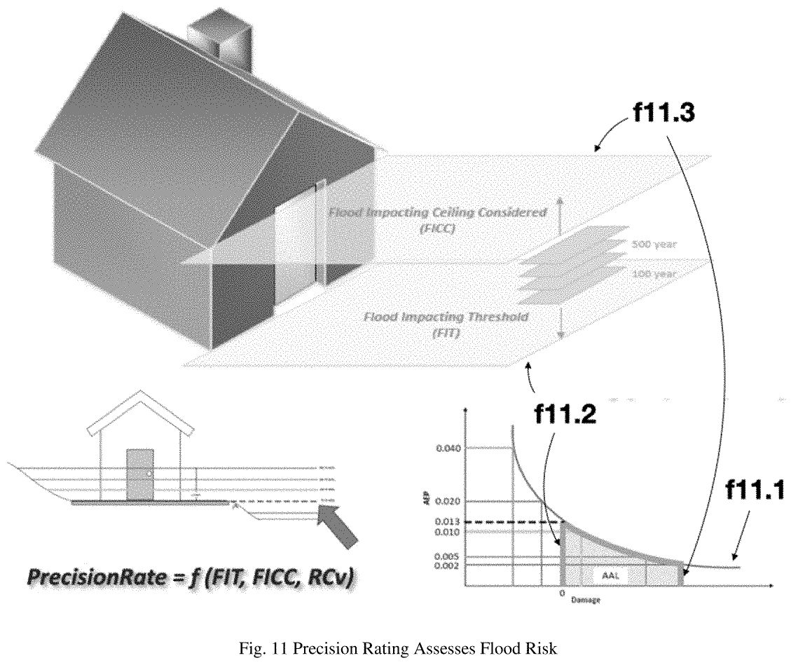

The present invention produces PrecisionRating, a precise flood risk rating based on the concept of Flood Impacting Threshold. PrecisionRate is dependent on three factors: Flood Impacting Threshold (FIT, FIG. 11, f11.2), Flood Impacting Ceiling Considered (FICC, FIG. 11, f11.3), and Rating Curve (RCv, FIG. 11, f11.1) used. The present invention rates such risk by setting FIT as the “lower boundary” critical to rating risk precisely and fully. It calculates the full risk by counting the full range between this “lower bound” and a chosen “upper bound” event. The result is often significantly, even dramatically, different from rates calculated based on other rating methods because those systematically under- or over-rate full risk. Illustrated in FIG. 11, the present invention conducts “PrecisionRating” of flood risk by setting both upper and lower boundary events on the rating curve (RCv, FIG. 11, f11.1), with the FIT event as the lower boundary (FIG. 11, f11.2) and Flood Impacting Ceiling Considered Event (FICC, FIG. 6, f11.3) as the upper boundary. PrecisionRating is superior in both grade and quality, rating flood risks precisely and fully, eliminating the common problems of flood insurance industry such as overrating or underrating for insurance policies. Based on structure characteristics, elevations and heights of structure or site, the present invention produces various depth products which is the difference between a structure elevation and water surface elevation. (For example, it determines the depth of 100-year or 500-year flood for a building.) The present invention determines whether a building's floor is above or below (InstantAoB) a certain water surface elevation of a certain frequency.

The present invention produces Annualized Average Depth (AAD) based on water surface elevation modeling and structure elevation determination. AAD is the average of water depth in any given year calculated over several water events. Various water events can happen in any given year. The chance of the occurrence of any water event in any given year can be probabilistically determined and represented as probability distribution. The mean of the probability distribution of water depth is the AAD. Flooding is one type of water events. Flooding can happen when water overflows river or sewer system due to, for example, rainfall events. To produce water depth, water surface elevation and terrain elevation is required. Water surface elevation can be determined using various methods including hydrology & hydraulics analysis from various inputs including stream flow, rainfall. Stream flow is one of the most critical inputs for determining water surface elevation. Stream flow changes with time and a specific stream flow can occur at different frequency. The frequency of stream flow can be determined using frequency analysis. Frequency analysis can provide a probability of the occurrence of stream flow at any given return period. At any given location, water depth can be determined by subtracting terrain elevation from water surface elevation obtained from stream flow associated with the probability of its occurrence. Various water depths can be probabilistically distributed at any given year. The mean of the probability distribution of water depth is the annualized average depth.

The present invention produces terrain characteristics of a structure or site, such as Lowest Adjacent Grade, Highest Adjacent Grade, Median Adjacent Grade, etc. It will be apparent to those skilled in the art that various modifications and variations can be made to the system and method of the present disclosure without departing from the scope or spirit of the disclosure. It should be perceived that the illustrated embodiments are only preferred examples of describing the invention and should not be taken as limiting the scope of the invention.

1. A system for generating, managing, and serving information on structural characteristics and analytics, comprising:
a storage means for storing and retrieving data;
an input data means for managing inputs;
a querying means for requesting said data;
a server connected to said storage means;
a communication means is connected to said system for interaction and communication;
a data acquiring means is connected to said communication means;
an observation means for observing and sensing object/feature of interest;
a location means for locating said object of interest is connected to said system and to said observation means;
an analytical management means for acquiring and managing data from said observation means is connected to said location means; and
a display having a Graphic User Interface (GUI) is connected to said communication means.

2. The system for generating, managing, and serving information on structural characteristics and analytics in accordance to claim 1, further comprising a collection of components connected to said data acquiring means and to said observation means, including:
an image analysis means for image and imagery analysis;
an Artificial Intelligence (AI) and Computer Vison (CV) means;
a statistic and regression mean;
a reference means for setting Z-reference; and
a survey means for conducting virtual surveys of a structure or a site.

3. The system for generating, managing, and serving information on structural characteristics and analytics in accordance to claim 2, further comprising:
an elevation means for determining elevations and heights;
a certification means for certifying information; and
a certificate comprising information of building, building characteristics, elevations, and heights.

4. The system for generating, managing, and serving information on structural characteristics and analytics in accordance to claim 3, wherein the elevation means further comprising:
an Elevation Application Programming Interface (API) means for serving and requesting structure elevation and site elevation on-demand.

5. The system for generating, managing, and serving information on structural characteristics and analytics in accordance to claim 4, wherein the ElevationAPl means' outputs including:
a Lowest Adjacent Grade (LAG);
a Highest Adjacent Grade (HAG);
a Top of slab elevation;
a Floor elevation;
a Floor Height above terrain; and
a Floor height over top-of-slab.

6. The system for generating, managing, and serving information on structural characteristics and analytics in accordance to claim 3, wherein the certification means further comprising:
a) a Self-certification means;
b) a Professional certification means;
c) a User-aided certification means; and
d) a Re-run means having extra inputs for taking, marking up, and uploading photos.

7. The system for generating, managing, and serving information on structural characteristics and analytics in accordance to claim 1, wherein the Graphic User Interface (GUI) means further comprises:
a photo taking means;
a photo uploading means; and
an on-screen digitization and bounding box mean.

8. The system for generating, managing, and serving information on structural characteristics and analytics in accordance to claim 1, further comprising a derivative means for creating derivatives and visualizations utilizing said input data including:
a Flood Impacting Threshold (FIT);
a Water Entry Threshold (WET);
a Flood Impacting Threshold Scores (FITS);
a PrecisionRating (PR); and
an Annualized Average (Water) Depth (AAD).

9. A method for generating, managing, and serving information on structural characteristics and analytics, comprising the steps of:
a) detecting and extracting objects on an image of structure;
b) measuring and calculating said objects' dimensions based on a recognized reference object of known dimensions;
c) using Artificial Intelligence (AI)/Computer Vision (CV) module to automate said detection and extraction of objects; and
d) predicting elevation and height based on regression relationships.

10. The method for generating, managing, and Serving Information on Structural Characteristics and Analytics in accordance to claim 9, further comprising the steps of:
a) setting principal point on a side-view image of a structure from camera/viewpoint location and height;
b) setting the Top-of-Slab (TOS) elevation;
c) setting adjacent grades;
d) setting vertical datum (Z-reference) for said image of structure;
e) detecting doors, garage doors, building footprints, and driveways; and
f) detecting special height objects.
